(19) United States
(12) Patent Application Publication
(10) Pub. No.: US 2003/0082845 A1
(43) Pub. Date: May 1, 2003

(54) PACKAGE FOR MULTIPLE INTEGRATED CIRCUITS AND METHOD OF MAKING

(75) Inventors: Mr. PAUL HOFFMAN, CHANDLER, AZ (US); Mr. VINCENT DICAPRIO, MESA, AZ (US); Mr. IL KWON SHIM, TEMPE, AZ (US)

Correspondence Address: James E. Parsons, Skjerven, Morrill, LLP, 25 Metro Drive Ste. 700, San Jose, CA, 95110, US, jparsons@skjerven.com, 408-453-9200

(73) Assignee: AMKOR Technology, Inc., Chandler, 85248 (US)

(21) Appl. No.: 09/483,212

(22) Filed: Jan. 14, 2000

(51) Int. Cl. H01L 21/44; H01L 21/48; H01L 21/50

(52) U.S. Cl. 438/106

(57) ABSTRACT

### Abstract of Disclosure

Embodiments of integrated circuit packages for housing a plurality of integrated circuits are disclosed, along with methods of making the packages. One embodiment of a package includes a substrate having a first surface with first metallizations thereon and an opposite second surface with second metallizations thereon. One or more apertures extend through the substrate between the first and second surfaces. Conductive vias also extend through the substrate. Eachof the vias electrically connect one or more of the first and second metallizations. A first integrated circuit having a first surface with first bond pads thereon and an opposite second surface is attached to the second surface of the substrate so that the first bond pads are superimposed with an aperture. At least one second integrated circuit is attached to the second surface of the first integrated circuit. An opposite surface of the second integrated circuit has edge bond pads thereon. Each of a plurality of first bond wires are electrically connected between a first metallization and a first bond pad. Each of a plurality of second bond wires are electrically connected between a second metallization and a second bond pad. Accordingly, the second integrated circuit is electrically connected to first metallizations by way of the viasthrough the substrate. The integrated circuits may be electrically connected to each other. In a second package embodiment, the first integrated circuit is a flip chip integrated circuit. In the second embodiment, apertures through the substrate are not necessary.

### Background of Invention

The present invention concerns packaging for integrated circuits. More particularly, the present invention is directed toward a high density package for a plurality of integrated circuits. Description of the Related Art Practitioners of integrated circuit packaging strive to reduce package size and cost, while improving or maintaining package reliability, performance, and density. A common approach to achieving these objectives is to employ a ball grid array ("BGA") package. BGA packages typically include an integrated circuit mounted on an insulative substrate. Metal bond pads located proximate to peripheral sides of the integrated circuit (hereinafter "edge bond pads") are connected by bond wires to traces on an upper surface of the substrate. The traces are connected by metallized vias through the substrate to solder balls on a lower surface of the substrate. An advantage of BGA packages is that a relatively large, but not unlimited, number of solder balls can be placed on the package.

In increase in the density of packaging has been achieved by housing a plurality of integrated circuits in a single package. FIG. 1 shows a known stacked package 1. Integrated circuits 2 and 3 each are attached to opposite surfaces of a substrate 4 by adhesive layers 16. Bond wires 5 are connected between edge bond pads 6 of integrated circuits 2 and 3 and leads 7of a leadframe. Mold compound 17 covers integrated circuits 2 and 3, bond wires 5, and an inner end of leads 7. This package design is not compatible with integrated circuits having bond pads located at a central region of a surface of the integrated circuits, i.e., approximately half-way between opposite peripheral sides of the integrated circuit (hereinafter "center bond pads"), because the bond wire lengths become too long. In addition, package 1 requires a leadframe and is relatively large.

FIG. 2 shows another known stacked package 8, which has solder balls like a BGA package. Integrated circuit 9 is attached to a metal die pad 10 on a polyimide tape substrate 11. Rows of edge bond pads 6 on integrated circuit 9 are attached by bond wires 5 to traces 12 on an upper surface of substrate 11. Traces 12 are electrically connected through substrate 11 to solder 35 balls 13. A smaller second integrated circuit 14 is attached by adhesive 16 to integrated circuit 9. Edge bond pads 15 on integrated circuit 14 are attached by additional bond wires 5 to certain edge bond pads 6 of integrated circuit 9. In this manner, integrated circuits 9 and 14 are electrically interconnected, but integrated circuit device 14 does not have a direct bond wire connection with a trace 12. In addition, package 8 is relatively large and only accommodates integrated circuits having edge bond pads.

In view of the shortcomings of such conventional packages, what is needed is a cost effective and reliable integrated circuit package having the input and output capability of a BGA package and the density of a stacked package. Ideally, the package also would have a small footprint.

### Summary of Invention

Embodiments of integrated circuit packages for housing a plurality of integrated circuits are disclosed, along with methods of making the packages. The packages have the input and output capability of BGA packages and the density of a stacked package, while having a footprint that is the same as, or nearly the same as, the footprint of an ordinary integrated circuit package for a single integrated circuit.

A first package embodiment includes a substrate having a first surface with first metallizations thereon, and an opposite second surface with second metallizations thereon. One or more apertures extend through the substrate between the first and second surfaces. A plurality of conductive vias also extend through the substrate. Each of the vias electrically connects one or more of the first and second metallizations.

A first integrated circuit having a first surface and an opposite second is mounted the second surface of the substrate. First bond pads on the first surface of the first integrated circuit are superimposed with an aperture. First bond wires each electrically connect a first bond pad to a first metallization. The first bond wires extend through an aperture. One or more second integrated circuits are attached to the second surface of the first integrated circuit. The second integrated circuits have edge bond pads. Bond wires electrically connect edge bond pads of the second integrated circuit(s) to second metallizations, which in turn are electrically connected by vias to first metallizations on the first surface of the substrate. Encapsulam material fills the one or more apertures. Encapsulant on the second surface of the substrate covers the first and second integrated circuits. Solder balls on the first metallizations allow electrical connection of the package to a printed circuit board.

The present invention also includes methods of making packages that house two or more integrated circuits. An exemplary method provides a substrate having a first surface with first metallizations thereon and an opposite second surface with second metallizations thereon. One or more apertures and conductive vias extend between the first and second surfaces of the substrate. Each of the vias electrically connects one or more of the first and second metallizations. A first integrated circuit having central bond pads and/or edge bond pads is mounted on the second surface of the substrate so that the bond pads are superimposed with an aperture. Next, one or more second integrated circuits are mounted on the first integrated circuit. The second integrated circuit(s) has edge bond pads. The bond pads of the first integrated circuit are wired to the first metallizations through an aperture. The bond pads of the second integrated 15 circuit(s) are wired to second metallizations. Accordingly, the second integrated circuit is electrically connected to first metallizations by way of the second bond wires and vias through the substrate. Encapsulant material is applied within the one or more apertures so as to cover the first bond wires. Encapsulant material also is applied on the second surface of the substrate so as to cover the stacked integrated circuit devices. Finally, solder balls are formed on the first metallizations so that the first and second integrated circuits may be electrically connected to a printed circuit board. These and other embodiment of the present invention, along with many of its advantages and features, are described in more detail below and are shown in the attached figures.

### Brief Description of Drawings

FIG. 1 is a cross-sectional side view of a conventional package 1 for integrated circuits 2 and 3.

FIG. 2 is a cross-sectional side view of a conventional package 8 for integrated circuits 9 and 14.

FIG. 3 is a cross-sectional side view of a package 20 for integrated circuits 25 and 30.

FIG. 4 is a cross-sectional side view of a package 60 for an integrated circuit 25 and two integrated circuits 30'.

FIG. 5 is a cross-sectional view of a package 65 for two stacks 66 of integrated circuits 25 and 30.

FIGs. 6A-6G are cross-sectional side views of stages in an exemplary method of assembling package 20 of FIG. 3FIG. 7 is a cross-sectional side view of a package 75 for integrated circuits 77 and 81.

FIG. 8 is a cross-sectional side view of a package 90 for a flip chip integrated circuit 91 and an integrated circuit 97.FIGs. 9A-9G are cross-sectional side views of stages in an exemplary method of assembling package 90 of FIG. 8.

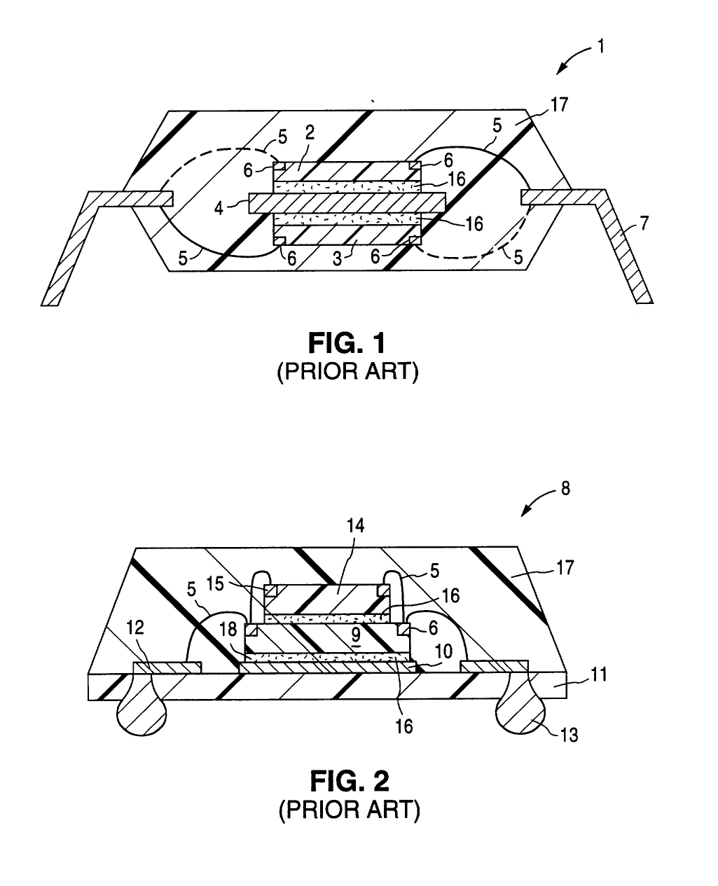

The occasional use of the same reference symbols in different drawings indicates similar or identical items.

### Detailed Description

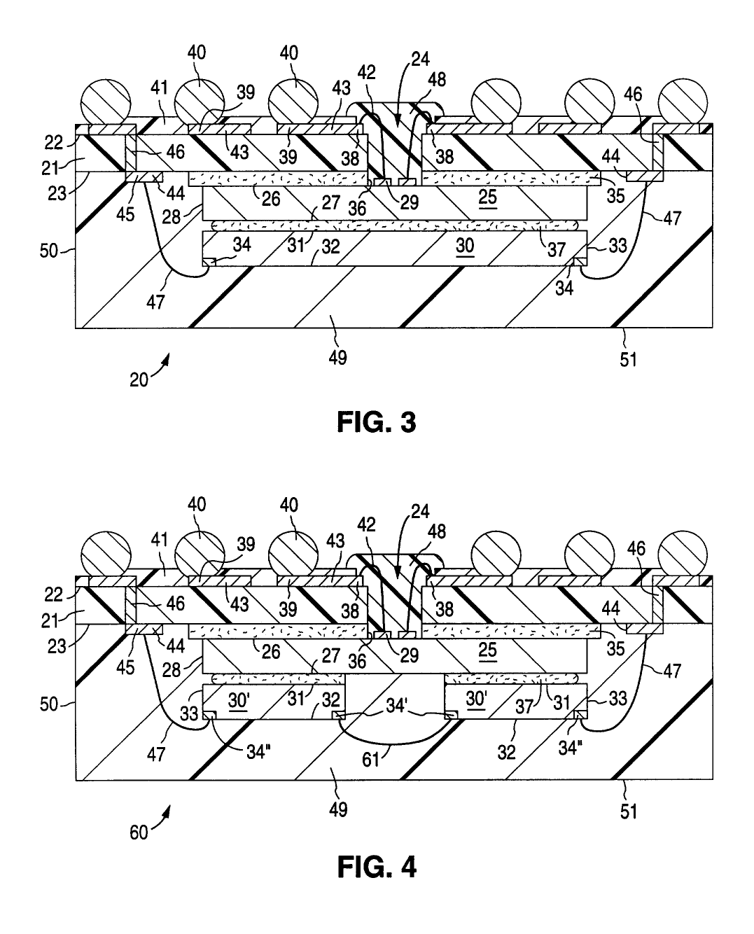

Figure 3 shows a package 20 in accordance with one embodiment of the present invention. Package 20 includes an insulative substrate 21 having two metal layers. Substrate 21 has a first surface 22, an opposite second surface 23, and a centrally located slot-like aperture 24 between first surface 22 and second surface 23. Substrate 21 may be formed from any conventional flexible or stiff insulative substrate material that is capable of withstanding chemical and thermal processes, such as plating, chemical etching, and soldering. As an example, the substrate 21 may be formed of polyimide, plastic, an epoxy laminate, or insulated metal. Alliteratively, substrate 21 may be comprised of layers of different materials, such as a polyimide layer and a stiff metal layer.

Package 20 also includes integrated circuit 25 and 30. Integrated circuit 25 includes a first surface 26, an opposite second surface 27, and peripheral side surfaces 28 between first surface 26 and second surface 27. First surface 26 includes two rows of conductive central bond pads 29 that are electrically connected to internal circuitry of integrated circuit device 25. Central bond pads 29 are approximately half-way between opposing side surfaces 28. An adhesive film 35 having a central aperture 36 attaches first surface 26 of integrated circuit 25 to 30second surface 23 of substrate 21 so that aperture 24 superimposes central bond pads 29. Other types of adhesives, such as a conventional epoxy adhesive layer, may be used in place of adhesive film 35.

Similarly, integrated circuit 30 includes a first surface 31, an opposite second surface 32, and peripheral side surfaces 33 between first surface 31 and second surface 32. Second surface 32 includes two rows of conductive edge bond pads 34. Each row of edge bond pads 34 is located proximate to opposing edges of second surface 32 of integrated circuit 30. Edge bond pads 34 are electrically connected to internal circuitry of integrated circuit 30. Edge bond pads 34, as well as center bond pads 29 of integrated circuit 25, typically are formed of polysilicon or metal, such as aluminum, and may be plated with other conventional metals, such as nickel and/or gold. A conventional adhesive film 37 attaches first surface 31 of integrated circuit 30 to second surface 27 of integrated circuit 25. Again, alternative conventional adhesives, such as epoxy, may be used instead of an adhesive film.

In package 20, integrated circuits 25 and 30 have the same, or approximately the same, dimensions. In alternative embodiments, one integrated circuit may be larger than the other (e.g., integrated circuit 30 may have a larger perimeter than integrated circuit 25). Integrated circuits 25 and 30 also may be the same type of integrated circuit. For example, integrated circuit chips 25 and 30 may both be memory (e.g., DRAM, SRAM, or flash memory), logic, or processor devices. Alternatively, integrated circuit chips 25 and 30 may be different types of integrated circuits, such as one memory device and one processor, or one SRAM and one DRAM.

First surface 22 and second surface 23 of substrate 21 include a plurality of electrically 20 conductive metallizations. For example, first surface 22 includes a plurality of metal bond sites 38 along opposing sides of aperture 24. Conductive metal traces 43 on first surface 22 connect bond sites 38 to metal solder ball lands 39. Conductive solder balls 40 are attached to lands 39 and provide input and output interconnects for package 20. An insulative cover coat 41 (e.g., solder mask material) optionally covers the traces on first surface 22 between solder balls 40 and 25 bond sites 38. A plurality of metal bond wires 42 arc each electrically connected between a center bond pad 29 of integrated circuit 25 and a bond site 38 In particular, each bond wire 42 extends from a center bond pad 29 though aperture 24 to a bond site 38 on first surface 22 of substrate 21.

Second surface 23 of substrate 21 includes a plurality of conductive metal bond sites 44 30 located between peripheral side surfaces 28 and 33 of integrated circuits 25 and 30, respectively, and package side surface 50. Conductive metal traces 45 on second surface 23 extend from bond sites 44 to metallized vias 46. A plurality of vias 46 extend through substrate 21 from first surface 22 to second surface 23. Vias 46 are each electrically connected to a trace 43 on first surface 22. The respective traces 43, in turn, may be electrically connected to lands 39 and 35 solder balls 40, or to bond sites 38 that are electrically connected by conventional bond wires 42, to central bond pads 29 of integrated circuit 25. Alternatively, a via 46 may be electrically connected to a bond site 44 without intervening traces 45, or electrically connected to a land 39 and solder ball 40 without an intervening trace 43. Additional conventional metal bond wires 47 electrically connect edge bond pads 34 on second surface 32 of integrated circuit 30 to bond sites 44 on second surface 23 of substrate 21. Accordingly, integrated circuit 30 is electrically connected through bond sites 44 and vias 46 to solder balls 40, and, optionally, to integrated circuit 25 through bond sites 38 and bond wires 42.

Traces 43 and 46, lands 39, bond sites 38 and 44, and vias 46 may be formed of conventional packaging metals, such as copper, aluminum, or solder. Traces 43 and 46, lands 39 and bond sites 38 and 44 may be plated with conventional plating metals, such as gold, nickel, 15 palladium, or combinations thereof. Bond wires 42 and 47 may be gold or other conventional metals.

A plug of a protective insulative first encapsulant 48 fills aperture 24 in substrate 21. First Encapsulant 48 adhesively covers a portion first surface 22 of substrate 21 adjacent to and around aperture 24, as well as bond sites 38, bond wires 42, central bond pads 29, and that 20 portion of first surface 26 of integrated circuit 25 that is juxtaposed with aperture 24. First encapsulant 48 may be formed of a conventional adhesive insulative mold compound, or alternatively, of a conventional adhesive insulative liquid encapsulant material.

A protective insulative second encapsulant 49 is formed on second surface 23 of substrate 21. Second encapsulant 49 adhesively covers second surface 23, bond sites 44, bond wires 47, and integrated circuits 25 and 30. Second encapsulant 49 may be formed of a conventional adhesive insulative mold compound, or alternatively of a conventional adhesive liquid encapsulant material. Package 20 has a planar exterior first surface 51 and orthogonal side surfaces 50 formed from second encapsulant 49 and the side surfaces of substrate 21.

FIG. 4 depicts another embodiment of a package within the present invention. Package 60 includes many of the same features of package 20 of FIG. 3. To minimize redundancy, the discussion will primarily highlight differences between the packages.

Package 60 of FIG. 4 includes a first integrated circuit 25 attached to second surface 23 of substrate 21, similar to package 20. Integrated circuit 25 is electrically connected to bond sites 38 by bond wires 42. Attached to second surface 27 of integrated circuit 25 of FIG. 3 are two smaller integrated circuits 30'. An adhesive film 37 attaches each integrated circuit 30' to integrated circuit 25. Each integrated circuit 30' has two rows of edge bond pads on its second surface 32. The edge bond pads are denoted as inner edge bond pads 34', which are along the side surface 33 adjacent to the other integrated circuit 30', and outer edge bond pads 34", which are adjacent to package sidewalls 50. Outer edge bond pads 34" are electrically connected by bond wires 47 to bond sites 44 on second surface 23 of substrate 21, and from there to solder balls 40 and/or to integrated circuit 25, as described above for package 20 of FIG. 3. One or more of the inner edge bond pads 34' of the each of the integrated circuits 30' are electrically connected to the other integrated circuit 30' by a bond wire 61. In this manner, the two integrated circuits 30' may be electrically connected.

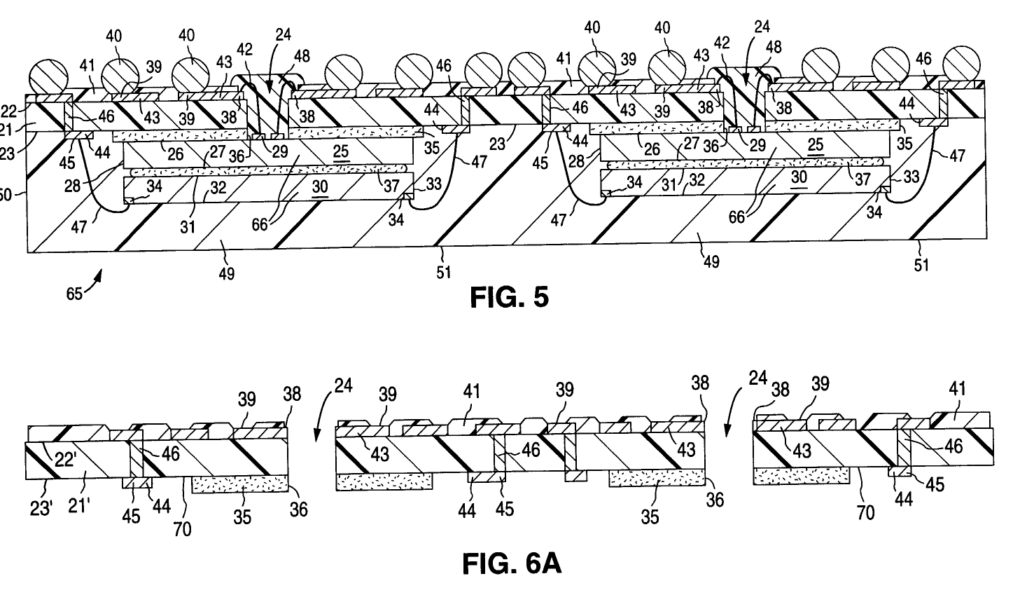

Referring to FIG. 5, another embodiment of the present invention provides a package 65 that is essentially two joined packages 20 of FIG. 3. Package 65 includes two integrated circuit stacks 66. Each stack 66 is comprised of integrated circuits 25 and 30. Additional traces 43 on first surface 22 of substrate may electrically connect the two stacks 66. In view of the similarities of package 65 to package 20 of FIG. 3, further discussion is unnecessary.

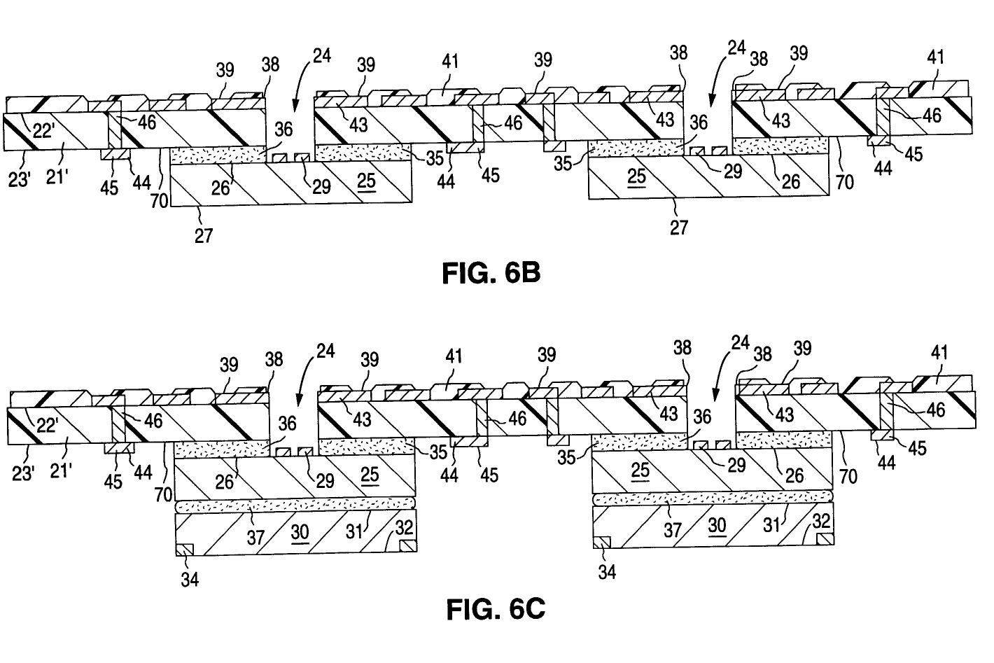

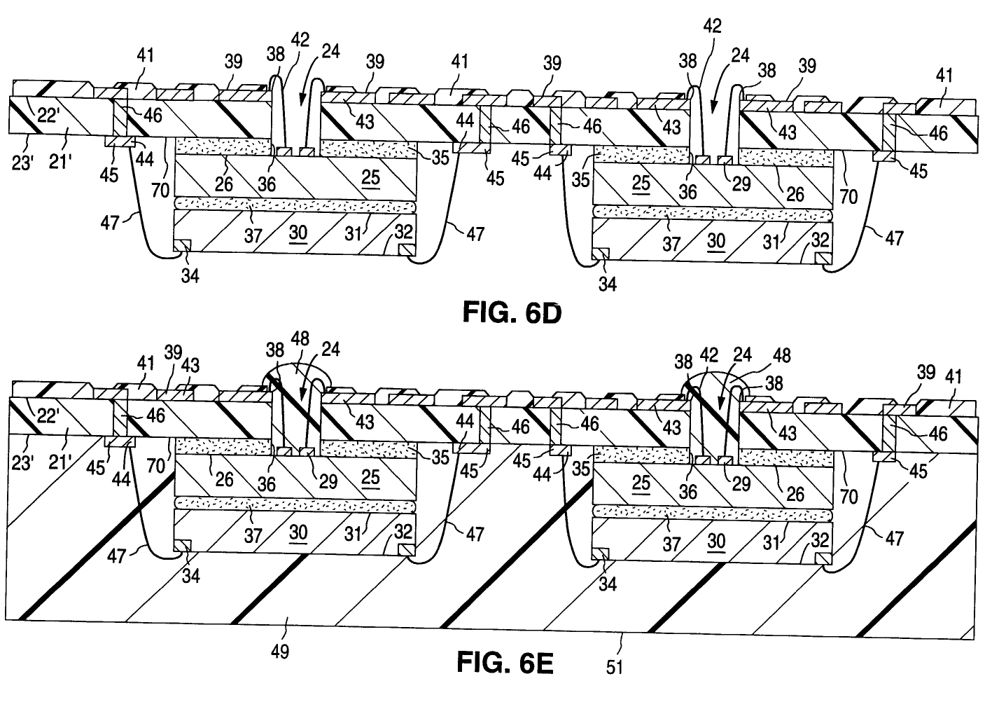

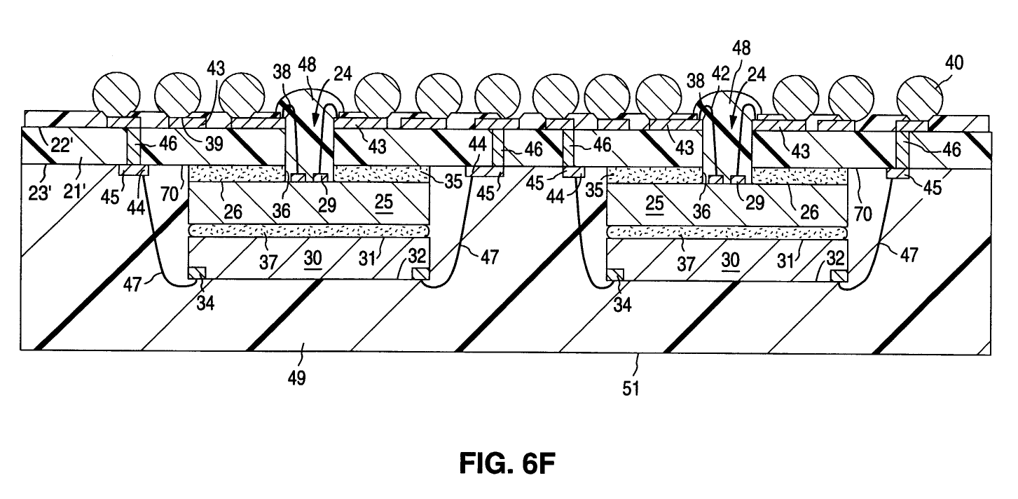

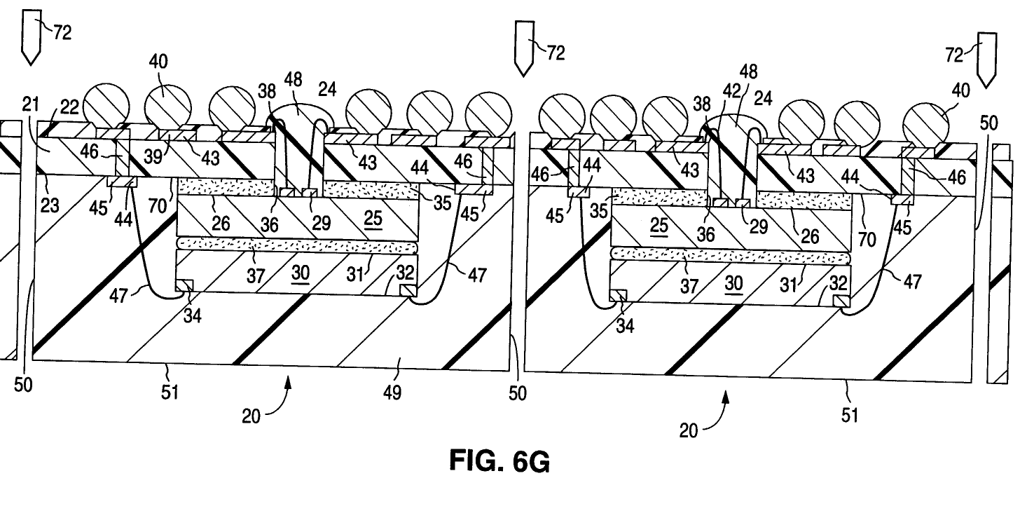

FIGs. 6A-6G provide cross sectional views of stages in an exemplary method of assembly of package 20 of FIG. 3. In this exemplary embodiment, package 20 is assembled in a batch process that assembles a plurality of packages 20 in parallel. Referring to FIG. 6A, an insulative substrate strip 21' having two metal layers thereon is provided. In particular, substrate strip 21' includes a plurality of identical package sites 70 in a matrix arrangement. A package 20 is assembled at each package site 70. Essentially, substrate strip 21' is a plurality of joined substrates 21 of FIG. 3. Each package site 70 includes an aperture 24, bond sites 38 and 44, lands 39, traces 43 and 45, vias 46, and, optionally, a cover coat 41. Lands 39 are exposed through apertures in cover coat 41. In addition, an adhesive film 35 is attached to second surface 23 of substrate strip 21' at each package site 70 adjacent to the respective aperture 24. Adhesive film 35 may be attached in any conventional manner. Adhesive film 35 also may be attached in the manner described in co-pending U.S. patent application 09/449,070 (attorney docket no. M-7896 US), entitled "Methods Of Attaching A Sheet Of An Adhesive Film To A Substrate In The Course Of Making Integrated Circuit Packages," which was filed on November 23, 1999, and isi ncorporated herein by reference.

Substrate 21' may be formed of any conventional insulative material, including an polyimide film, an epoxy laminate, or insulated metal, or combinations of such layers. The metallizations on substrate 21 and vias 46 may be formed by conventional methods, such as sputter or vapor deposition or electroplating and chemical etching.

Referring to FIG. 6B, a first surface 26 of an integrated circuit 25 is placed on the adhesive film 35 at each package site 70. Integrated circuit 25 may be a DRAM device or some other device. After a conventional curing process, adhesive film 35 attaches an integrated circuit 25 to second surface 23' of substrate strip 21' at each package site 70. Second surface 27 of integrated circuit 25 may be polished or otherwise ground to reduce the thickness of integrated circuit 25. Integrated circuit 25 may be placed on adhesive film 35 in the manner described in co-pending U.S. application no. 09/412,889 (attorney docket M-7899 US), entitled "Method Of Making An Integrated Circuit Package Using A Batch Step For Curing A Die Attachment Film And A Tool System For Performing The Method," which was filed on October 5, 1999 and is incorporated herein by reference.

Referring FIG. 6C, integrated circuit 30 is attached to second surface 27 of integrated circuit 25 using an adhesive film 37. Integrated circuit 30 may be a DRAM device or some other device. In one embodiment, a sheet of adhesive film is placed onto the wafer containing integrated circuit 30 and cured before integrated circuit 30 is sawed from the wafer. After the cutting step, each integrated circuit 30 is placed onto second surface 27 of integrated circuit 25 so that its adhesive film 37 contacts second surface 27. After a curing step, integrated circuit 30 is attached to integrated circuit 25.

First surface 31 of integrated circuit 30 may be polished or ground to reduce the thickness of integrated circuit 30. In addition, the edge bond pads 34 on integrated circuit 30 may have been relocated (e.g., changed from being central bond pads to edge bond pads).

In the above described process, adhesive films 35 and 37 are cured in separate curing steps. Alternatively, adhesive films 35 and 37 may be cured in a single curing step so that integrated circuit 25 adheres to substrate 21' at the same time integrated circuit 30 adheres to integrated circuit 25.

Referring to FIG. 6D, bond wires 42 are connected between respective center bond pads 29 and respective bond sites 38, and bond wires 47 are connected between edge bond pads 34 and bond sites 44. Substrate 21 is rotated between these two wiring steps. Conventional bond wiring techniques and materials are used.

Referring to FIG. 6E, encapsulant 48 is applied within aperture 24 and onto first surface 22' of substrate 21' around aperture 24 so as to cover the respective central bond pads 29, bond wires 42, and bond sites 38. Encapsulant 48 may be a molded using conventional insulative molding compounds and techniques. The height of encapsulant 48 above first surface 22' at each package site 70 is less that the expected height of solder balls 40 after attachment to a printed circuit board. In addition, encapsulant 49 is applied onto second surface 23' of substrate 21' at each package site 70 so as to form a protective covering over the respective integrated circuits 25 and 30, bond wires 47, and bond sites 44. Encapsulant 49 may be molded in a single block over all of the package sites 70 of substrate 21'. Encapsulant 49 may be molded using conventional insulative molding compounds and techniques. In one embodiment, encapsulant 48 and encapsulant 49 are simultaneously formed in a single molding operation. Alternatively, encapsulants 48 and 49 may be molded separately.

Referring to FIG. 6F, conventional solder balls 40 are attached to lands 39 at each package site 70 of substrate strip 21'. Conventional techniques may be used to form solder balls 40 on lands 39.

Finally, referring to FIG. 6G, individual packages 20 are separated from the encapsulatedarray of package sites 70. Individual packages 20 may be singulated by cutting between the encapsulated package sites 70 with a saw 72. The cutting action of saw 72 through encapsulant 49 and substrate 21' forms orthogonal side surfaces 50 on package 20.

Artisans will appreciate that an embodiment of a method of making package 60 of FIG. 4 25 is substantially the same as the above-described method of making package 20 of FIGs. 3 and 6A-6G. A difference in the methods is that two smaller integrated circuits 30' are attached to second surface 27 of integrated circuit 25 using adhesive films 37. Bond wires 47 and 61 are attached by conventional methods and formed of conventional metals.

Artisans also will appreciate that an embodiment of a method of making package 65 of FIG. 5 is substantially the same as the above-described method of making package 20 of FIGs. 3 and 6A-6G. A difference in the methods is that the encapsulated package sites 70 are cut so that two stacks 66 are included in each package.

FIG. 7 is an exemplary embodiment of a package 75 within the present invention. Package 75 is similar to package 20 of FIG. 3, except that package 75 includes two apertures 24 in. substrate 21 and two stacked integrated circuits 77 and 81 each having edge bond pads 34. Integrated circuits 77 and 81 could be two identical memory devices (e.g., two flash memory integrated circuits), although the types of integrated circuits may vary. Integrated circuits 77 and81 may have been thinned by a polishing or other grinding process, as discussed above, to yield a thinner package.

In particular, package 75 includes a substrate 76 having two patterned metal layers thereon. Substrate 76 also has two parallel apertures 24. Each aperture 24 is parallel to and adjacent to an opposite side 50 of package 75. Having two apertures 24 accommodates the two sets of edge bond pads 34 on integrated circuit 77. Substrate 76 may be formed of the same materials as substrate 21 of FIG. 3 (e.g., an epoxy laminate material or a polyimide material).

Substrate 76 of package 75 has a first surface 78, an opposite second surface 79, and metal vias 46 therebetween. First surface 78 is similar to first surface 22 of substrate 21 of FIG. 3. In particular, first surface 78 includes bond sites 38, traces 43, lands 39, and solder balls 40 on opposing sides of each of the two apertures 24. Traces 43 may go around apertures 24 to effect interconnections, e.g., between integrated circuits 77 and 81. In an alternative embodiment (not shown), bond sites 38, traces 43, lands 39, and solder balls 40 are located on first surface 78 only between the apertures 24.

Second surface 79 of substrate 76 is similar to second surface 23 of substrate 21, including having bond sites 44 and traces 45 thereon.

Integrated circuit 77 of package 75 of FIG. 7 has a first surface 84 attached to second surface 79 of substrate 76 by an adhesive film 35, and an opposite second surface 85 attached to first surface 82 of integrated circuit 81 by an adhesive film 37. Integrated circuits 77 and 81 may be electrically interconnected similar to integrated circuits 25 and 30 of FIG. 3.

Package 75 includes two plugs of encapsulant 48. Each plug of eneapsulant 48 fills one of the two apertures 24. Each plug of eneapsulant 48 contacts first surface 84 of integrated circuit 77 and covers the associated edge bond pads 34, bond wires 42, and bond sites 38. Encapsulant 48 also covers the portions of first surface 78 of substrate 76 adjacent to apertures 24. Encapsulant 49 on second surface 79 of substrate 76 covers integrated circuits 77 and 81, bond wires 47, bond sites 44, and traces 45.

Artisans will appreciate that an embodiment of a method of making package 75 of FIG. 7 is substantially the same as the above-described method of making package 20 of FIGs. 3 and 6A-6G. A difference in the methods is due to the presence of two sets of edge bond pads 34 on integrated circuit device 77, rather than central bond pads. Both sets of edge bond pads 34 on integrated circuit 77 are electrically connected by bond wires 42 to bond sites 38 on first surface 79 through an aperture 24, and both apertures 24 are filled with molded insulative encapsulant 48.

Artisans also will appreciate that package 75 of Figure 7 can be modified to have three integrated circuits similar to package 60 of FIG. 4.

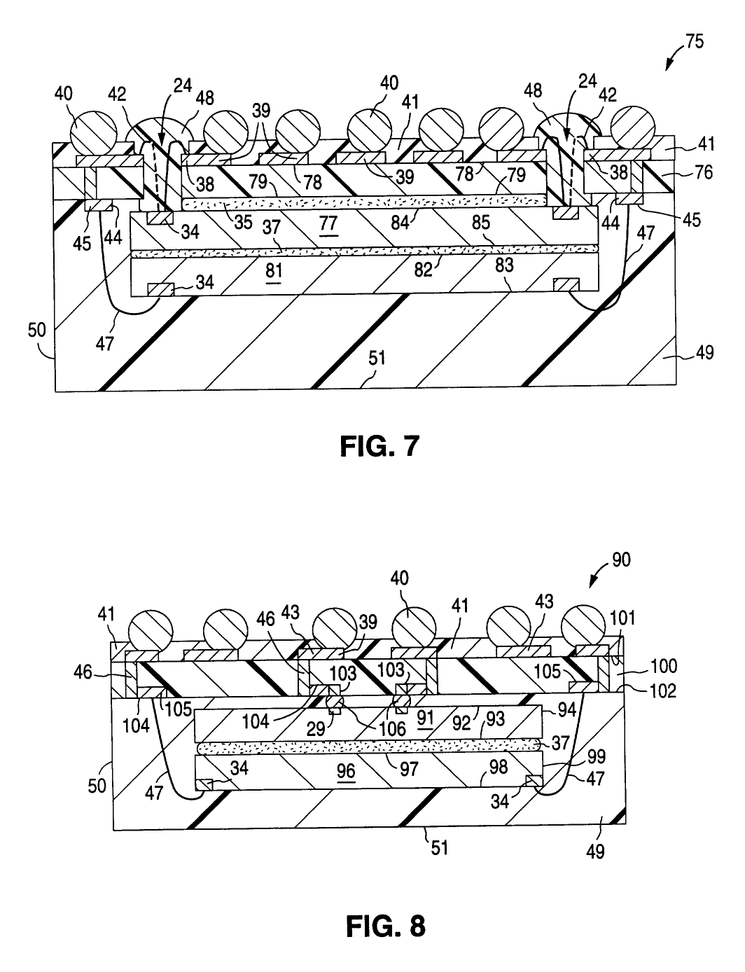

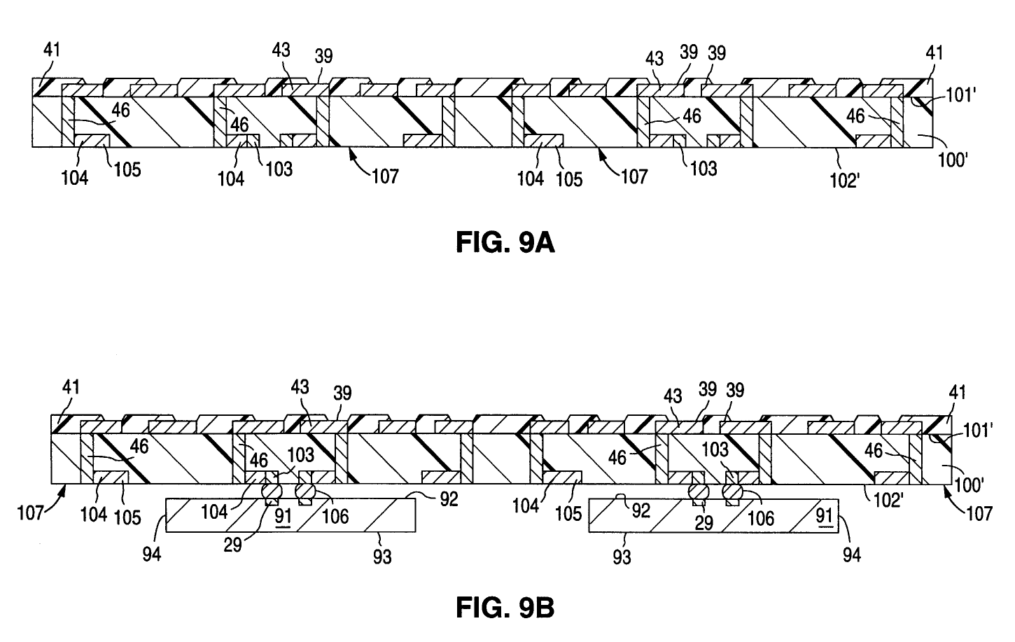

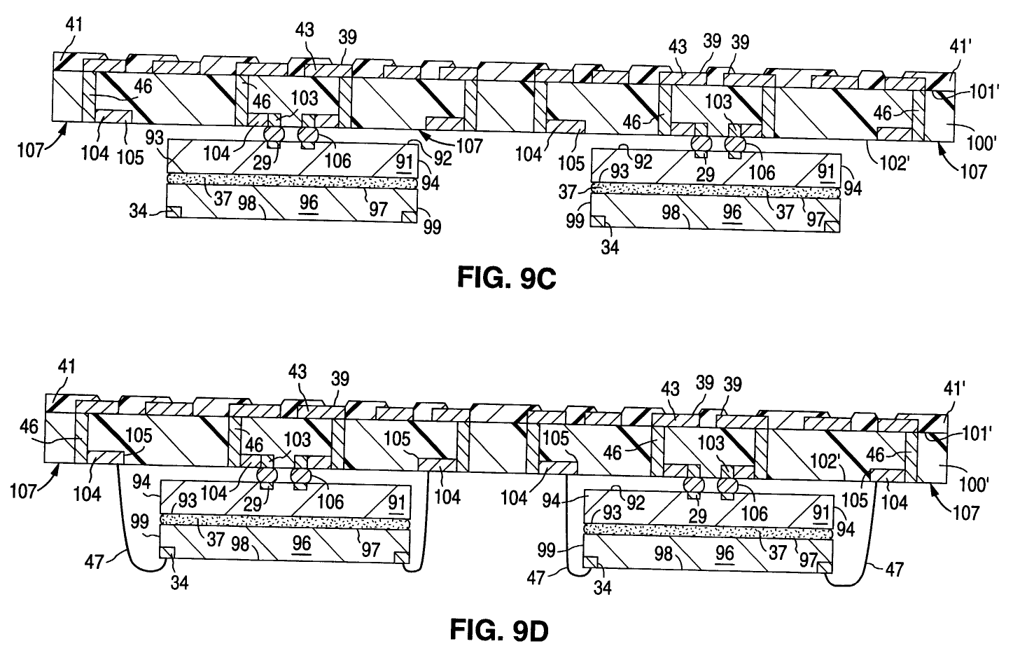

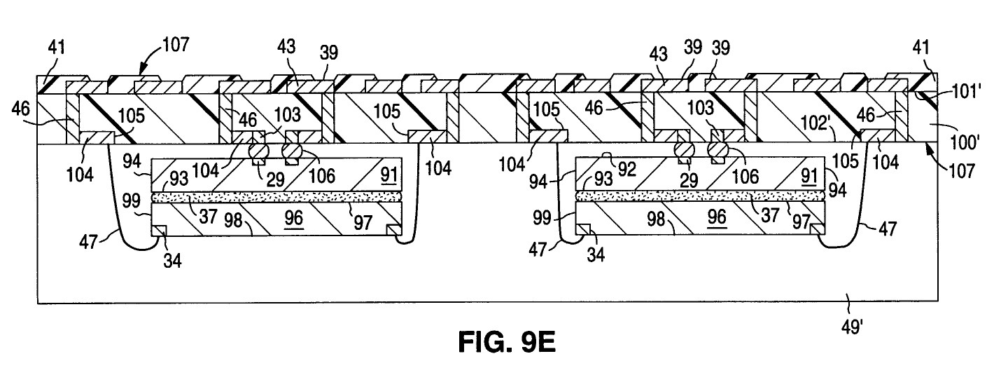

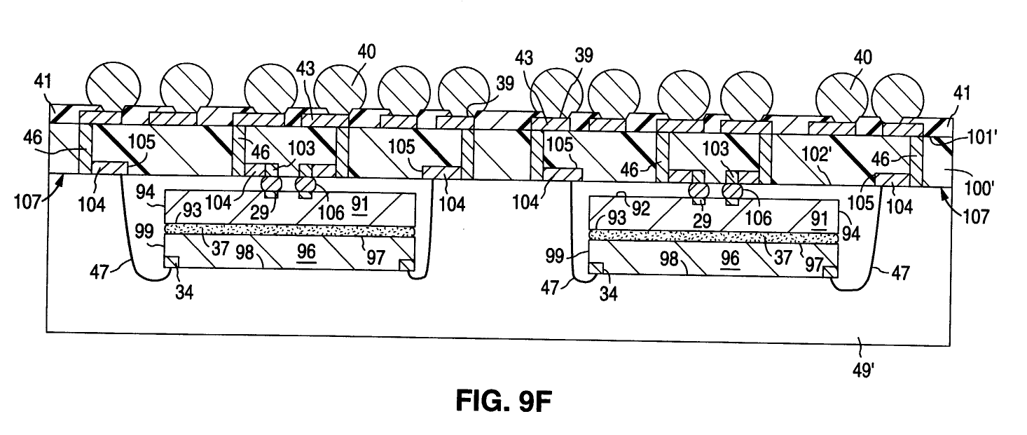

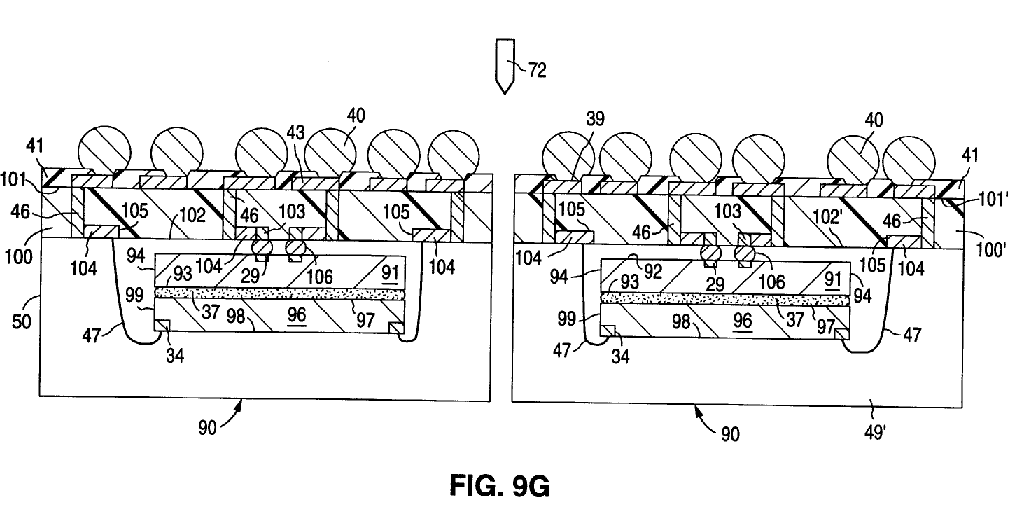

FIG. 8 is an embodiment of an alternative package 90 having stacked integrated circuits 91 and 96. Integrated circuit 91 is a flip chip integrated circuit having a first surface 92, an opposite second surface 93, and peripheral side surfaces 94. First surface 92 includes two rows of center bond pads 29, although in alternative embodiments integrated circuit 91 may have edge bond pads or may have a checkerboard arrangement of bond pads. Integrated circuit 96 of package 90 has a first surface 97, an opposite second surface 98 with edge bond pads 34, and peripheral side surfaces 99. First surface 97 is attached by an adhesive film 37 or equivalent to second surface 93 of integrated circuit 91.

Package 90 also includes an insulative substrate 100 having patterned metal layers on first surface 101 and opposite second surface 102, and metal vias 46 electrically connected between metallizations on first surface 101 and second surface 102. Second surface 102 includes a plurality of centrally-located metal contacts 103 thereon. Solder connections 106 each connect a central bond pad 29 of integrated circuit 91 to a metal contact 103. Contacts 103 are each electrically connected by a metal trace 104 to a metal via 46. Metal via 46 is electrically connected by a trace 43 and land 39 to a solder ball 40 on first surface 101 of substrate 100. Edge bond pads 34 of integrated circuit device 96 are each electrically connected by a bond wire 47 to a bond site 105. Bond sites 105 are each electrically connected to a trace 104 that in turn is electrically connected to a via 46, trace 43, land 39, and solder ball 40. In an alternative embodiment, one or more contacts 103 are each electrically connected to a bond site 105 on second surface 102, which in turn is electrically connected to integrated circuit 96. In this manner, integrated circuits 91 and 96 may be electrically connected. A cover coat of solder mask material may be on first surface 101 and second surface 102 of substrate 100.

Package 90 also includes an insulative encapsulant 49 on second surface 102 of substrate100. Encapsulant 49 covers flip chip integrated circuit 91 and integrated circuit 96, as well as bond wires 47, traces 104, and bond sites 105. Side surfaces 50 of package 90 are orthogonaland are formed from encapsulant 49 and substrate 100.

FIGs. 9A-gG provide cross sectional views of stages in an exemplary method of assembly of package 90 of FIG. 8. This exemplary method assembles a plurality of packages 90 in parallel. Referring to FIG. 9A, an insulative substrate strip 100' is provided having two patterned metal layers thereon. In particular, substrate strip 100' includes a plurality of identicalpackage sites 107 in a matrix arrangement. A package 90 is assembled at each package site 107. Essentially, substrate strip 100' is a plurality of joined substrates 100 of FIG. 8. Each package site 107 includes traces 43 and 104, vias 46, bond sites 105, lands 39, and contacts 103, as shown in FIG. 8.

Referring to FIG. 9B, a flip chip integrated circuit 91 is placed on second surface 102' of substrate strip 100' at each package site 107. An electrical connection is made by forming solder connections 106 between center bond pads 29 and metal contacts 103 on second surface 102' at the respective package sites 107. Underfill material may be applied between first surface 92 of each flip chip integrated circuit 91 and second surface 102' of each package site 107.

Referring to FIG. 9C, first surface 97 of integrated circuit device 96 is attached by an adhesive film 37 or equivalent to second surface 93 of flip chip integrated circuit 92. Referring to FIG. 9D, gold or other metal bond wires 47 are electrically connected between bond sites 105 on second surface 102' at each package site 107 and the edge bond pads 34 of the respective integrated circuit 96. Subsequently, as shown in FIG. 9E, encapsulant 49 is formed on second 25surface 102' using conventional insulative molding compounds and techniques on equivalent liquid encapsulation techniques. In one embodiment, all of the package sites 107 of substrate strip 100' are encapsulated in a single block of molded encapsulant 49'. Subsequent steps include attachment of solder balls 40 to lands 39 of first surface 101' at each package site 107(FIG. 9F), and separation of individual packages 90 by sawing through substrate 100' and the block of encapsulant 49' (FIG. 9G).

The above described packages and methods highlight some of the features of the present invention, such a providing stacked packages having a footprint that is the same as, or very close to, the footprint of a non-stacked package. In addition, the packages can be very thin, especially when the integrated circuits are polished to be ultra thin. The packages are made of conventional materials using conventional techniques, and hence are reliable.

The embodiments described herein are merely examples of the present invention. Artisans will appreciate that variations are possible within the scope of the claims.

Claims

1. An integrated circuit package comprising: a substrate having a first surface having first metallizations thereon, an opposite second surface having second metallizations thereon, one or more apertures between the first and second surfaces, and conductive vias through the substrate between the first and second surfaces, each of said vias electrically connecting one or more of said first and second metallizations; a first integrated circuit having a first surface with first bond pads thereon, and an opposite second surface, wherein the first bond pads are superimposed with an aperture; at least one second integrated circuit having a first surface and an opposite second surface with conductive second bond pads thereon, wherein the first surface of the at least one second integrated circuit is on the second surface of the first integrated circuit; a plurality of first bond wires, each first bond wire being electrically connected between a first metallization and a first bond pad, said first bond wires extending through an aperture; and " a plurality of second bond wires, each second bond wire being electrically connected between a second metallization and a second bond pad, whereby the second integrated circuit is 20 electrically connected to first metallizations.

2. The package of claim 1, wherein at least one first bond pad is electrically connected to at least one second bond pad.

3. The package of claim 1, wherein the first and second integrated circuits are the same type of integrated circuit.

4. The package of claim 1, wherein the first and second integrated circuits are different types of integrated circuits.

5. The package of claim 1, wherein at least some of the first bond pads are center bond pads, and the second bond pads are edge bond pads.

6. The package of claim 1, further comprising a plurality of said second integrated circuits.

7. The package of claim 6, wherein at least one second bond pad of one second integrated circuit is electrically connected to at least one second bond pad of another second 10 integrated circuit.

8. The package of claim 1, wherein said substrate includes a plurality of said apertures, each of said apertures superimposes first bond pads, and bond wires extend through each aperture and electrically connect first bond pads to first metallizations.

9. The package of claim 8, wherein at least some of the first bond pads are edge bond pads.

10. The package of claim 9, wherein the first and second bond pads are edge bond 20 pads.

11. The package of claim 8, further comprising a plurality of solder balls each on a first metallization of the first surface of the substrate, wherein each solder ball is electrically connected to at least one first or second bond pad, and solder balls are located adjacent to opposite sides of each said aperture.

12. The package of claim 11, wherein at least some of the first bond pads are edge bond pads.

13. The package of claim 8, wherein at least one first bond pad is electrically connected to at least one second bond pad.

14. An integrated circuit package comprising: a substrate having a first surface having first metallizations thereon, an opposite second 35 surface having second metallizations thereon, and a plurality of conductive vias through the substrate between the first and second surfaces, each of said vias electrically connecting one or more of said first and second metallizations; a flip chip integrated circuit having a first surface with first bond pads thereon and an opposite second surface, wherein the first bond pads face the second surface of the substrate, and each said bond pad is electrically connected to at least one of said second metallizations; at least one second integrated circuit having a first surface and an opposite second surface with second bond pads thereon, wherein the first surface of the at least one second integrated
circuit is on the second surface of the first integrated circuit; and a plurality of bond wires, each bond wire being electrically connected between a second bond pad and a second metallization, whereby the at least one second integrated circuit is electrically connected to first metallizations.

15. The package of claim 14, wherein the second bond pads are edge bond pads.

16. The package of claim 15, further comprising a plurality of said second integrated 20 circuits.

17. A method of making a package containing a plurality of integrated circuits, the method comprising: providing a substrate having a first surface having first metallizations thereon, an opposite second surface having second metallizations thereon, one or more apertures between the first and second surfaces, and conductive vias through the substrate between the first and second surfaces, each of said vias electrically connecting one or more of said first and second metallizations; providing a first integrated circuit having a first surface with first bond pads thereon and an opposite second surface, and mounting the first surface of said first integrated circuit on the second surface of the substrate so that the first bond pads are superimposed with an aperture providing at least one second integrated circuit having a first surface and an opposite second surface with second bond pads thereon, and mounting the first surface of said at least one second integrated circuit on the second surface of the first integrated circuit; providing a plurality of first bond wires, and electrically connecting each first bond wire between a first bond pad and a first metallization through an aperture; and providing a plurality of second bond wires, and electrically connecting each second bond wires between a second bond pad and a second metallization, whereby the second integrated circuit is electrically connected to first metallizations.

18. The method of claim 17, further comprising electrically connecting at least one of said first bond pads to at least one of said second bond pads.

19. The method of claim 18, wherein at least some of the first bond pads are center 15 bond pads, and the second bond pads are edge bond pads.

20. The method of claim 19, wherein the first and second bond pads are edge bond pads.

21. The method of claim 17, further comprising providing a plurality of said apertures, and mounting said first integrated circuit device so that each of said apertures superimposes first bond pads.

22. The method of claim 21, wherein at least some of the first bond pads are center 25 bond pads, and the second bond pads are edge bond pads.

23. The method of claim 22, wherein the first and second bond pads are edge bond pads.

24. A method of making a plurality of packages each containing a plurality of integrated circuits, the method comprising: providing a planar substrate having a plurality of package sites thereon, wherein each package site has a first surface having first metallizations thereon, an opposite second surface having second metallizations thereon, one or more apertures between the first and second surfaces, and a one or more conductive vias through the substrate between the first and second surfaces, each of said vias electrically connecting one or more of said first and second metallizations; providing a plurality of first integrated circuits each having a first surface with conductive first bond pads thereon, and an opposite second surface, and placing the first surface of said first integrated circuit on the second surface of the substrate at each package site so that the first bond pads are superimposed with an aperture of the package site; providing a plurality of second integrated circuits each having a first surface and an opposite second surface with conductive second bond pads thereon, and placing the first surface of at least one second integrated circuit on the second surface of the first integrated circuit of each package site; providing a plurality of conductive first bond wires for each package site, and electrically
connecting each first bond wire between a first bond pad and a first metallization through an aperture at the respective package sites; and providing a plurality of conductive second bond wires for each package site, and electrically connecting each second bond wire between a second bond pad and a second metallization at the respective package sites, whereby the second integrated circuits are electrically connected to first metallizations of the respective package site.

25. The method of claim 24, further comprising electrically connecting at least one of said first bond pads to at least one of said second bond pads.

26. The method of claim 23, wherein at least some of the first bond pads are center bond pads, and the second bond pads are edge bond pads.

27. The method of claim 24, further comprising providing a plurality of said apertures at each package site, and mounting the first integrated circuit at each package site so that each of said apertures superimposes first bond pads.

28. The method of claim 27, further comprising electrically connecting at least one of said first bond pads to at least one of said second bond pads.

29. The method of claim 27, wherein at least some of the first bond pads are center bond pads, and the second bond pads are edge bond pads.

30. The method of claim 27, wherein the first bond pads are edge bond pads.

31. A method of making a package containing a plurality of integrated circuits, the method comprising: providing a substrate having a first surface having first metallizations thereon, an opposite second surface having second metallizations thereon, and a plurality of conductive vias through the substrate between the first and second surfaces, each of said vias electrically connecting one or more of said first and second metallizations; providing a flip chip integrated circuit having a first surface with first bond pads thereon and an opposite second surface; mounting the first surface of the flip chip integrated circuit on the second surface of the substrate so that the first bond pads face the second surface of the substrate, and electrically connecting said at least some of said first bond pads to respective said second metallizations;
providing at least one second integrated circuit having a first surface and an opposite second surface with conductive second bond pads thereon, and mounting the first surface of the at least one second integrated circuit on the second surface of the first integrated circuit; and providing a plurality of bond wires, and electrically connecting each bond wire between a second bond pad and a second metallization, whereby the at least one second integrated circuit is electrically connected to first metallizations.

32. The method of claim 31, wherein the second bond pads are edge bond pads.
